(19) United States
(12) Patent Application Publication
(10) Pub. No.: US 2007/0111113 A1
(43) Pub. Date: May 17, 2007

(54) Photo mask for mitigating stitching effect and exposing method using the same

(75) Inventor: Hung-Yu Chen, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/599,002

(22) Filed: Nov. 13, 2006

(30) Foreign Application Priority Data
Nov. 11, 2005 (TW) 94139754

(51) Int. Cl. G03C 5/00; G03F 1/00

(52) U.S. Cl. 430/5; 430/394

(57) ABSTRACT

A mask which can mitigate the so-called stitching effect. The mask includes a plurality of blocks. The stitching area between two adjacent blocks is nonlinear. In an exposure process of the glass substrate for liquid crystal display, the mask can alleviate the substrate from stitching effect while exposing the glass substrate, so as to decrease beeline effect of the stitching area. An exposing method using the mask is also provided.

### BACKGROUND OF THE INVENTION

1. Field of the Invention

The present invention relates to photo masks and exposure methods using photo masks, and particularly to a photo mask for mitigating the so-called stitching effect and an exposure method using such photo mask.

2. General Background

The process of manufacturing thin film transistors (TFTs) for an array substrate of a liquid crystal display generally includes several steps of treatment of a glass substrate. Such steps include thin film coating, photolithographic processes, forming of TFTs, etc. The photolithographic processes mainly include film coating, cleaning, photo-resist coating, exposing, developing, etching, stripping, inspecting, subsequent film coating, subsequent cleaning, etc. In the exposing process, a photo mask (also known simply as a “mask”) is used for selectively irradiating a coating of photo-resist on the glass substrate with light such as UV light. The photo-resist coating is then developed. The quality of the exposure process has a direct impact on the quality of the TFTs produced, which in turn affects the display quality of a screen of the liquid crystal display. Therefore, the mask plays an important role in the exposure process.

Referring to FIG. 6, this is a schematic plan view of a layout of a conventional mask. The mask 20 has three blocks, which are designated as block I, block II, and block III. Each of so-called stitching regions between respective adjacent blocks I, II, and III is wavy. In an exposure procedure, the mask 20 is utilized to expose a glass substrate 10 from a left side of the glass substrate 10 to a right side of the glass substrate 10. Typically, the glass substrate 10 has a photo-resist coating (not shown) thereon. During the exposing process, light is irradiated through block I of the mask 20 to form an exposed area 1 on the glass substrate 10. Then light is irradiated through block II of the mask 20 to form exposed areas 2, 3, and 4 on the glass substrate 10. Finally, light is irradiated through block III of the mask 20 to form an exposed area 5 on the glass substrate 10. Due to the stitching regions among the blocks I, II, III of the mask 20 being wavy, boundaries between the respective adjacent exposed areas 1, 2, 3, 4, 5 on the glass substrate 10 have corresponding stitching regions, which are also wavy. For example, a stitching region 8 is formed between the two adjacent exposed areas 4 and 5.

FIG. 7 is a schematic, enlarged view of the stitching region 8, showing how it is finally formed over the course of two exposure steps in the above-described exposure procedure. The stitching region 8 includes three regions 81, 82, 83. The reference number 8A indicates the stitching region 8 when the stitching region 8 undergoes an earlier of said exposure steps. In this earlier exposure step, the regions 81 and 82 are exposed through the block II of the mask 20. The reference number 8B indicates the stitching region 8 when the stitching region 8 undergoes a later of said exposure steps. In this later exposure step, the regions 82 and 83 are exposed through the block III of the mask 20. The stitching region 8 finally obtained is in effect a combination of the stitching region 8 represented by reference number 8A and the stitching region 8 represented by reference number 8B. As seen, the region 82 finally obtained has undergone double exposure through block II and then block III of the mask 20. This can result in serious variation occurring in subsequent photolithographic processes performed, such as in developing, etching, stripping, inspecting, etc. For example, subsequent processes performed on photo-resist coating may be non-uniform. The upshot may be significant gray level variation on the screen of the liquid crystal display.

For example, a viewer may see a whole line that corresponds to the stitching region 8. Referring to FIG. 8, this is a schematic, enlarged view of portions of the regions 82, 83 where they adjoin each other, showing the stitching effect. When the intensity of exposure through the block II of the mask 20 is greater than the intensity of exposure through the block III, as seen, a corresponding shadow distribution in region 82 is more concentrated than a corresponding shadow distribution in region 83. Therefore, the result of the exposing process at the stitching region 8 is different from that of other portions of the exposed areas 4, 5. Thus the optical characteristics of the glass substrate 10 once finally formed are different as between the stitching region 8 and the exposed areas 4, 5. Accordingly, a straight bright line (or dark line) may exist on the glass substrate 10, and diminish the display quality of images shown on the screen of the liquid crystal display.

### SUMMARY

A exemplary mask for improving stitching effect includes several blocks where the stitching areas between two adjacent blocks is nonlinear.

An exemplary exposing method for using a mask to miligate stitching effect is also provided, the mask having at least a first block and a second block wherein the first block adjoins the second block. The method has following steps: forming a first exposed area on a target substrate by exposing the substrate with light through the first block of the mask; and forming a second exposed area on the substrate by exposing the substrate through the second block of the mask. A stitching area where the first block and the second block adjoin each other is nonlinear.

A detailed description of embodiments of the present invention is given below with reference to the accompanying drawings. In the drawings, all the views are schematic.

### BRIEF DESCRIPTION OF THE DRAWINGS

FIG. 1 is a plan view of a mask according to a first embodiment of the present invention, together with a substrate used with the mask in an exposing process according to a fourth embodiment of the present invention, the substrate having a stitching region formed thereon.

FIG. 2 is an enlarged view of part of the stitching region shown in FIG. 1, the part shown corresponding to a plurality of pixels of a liquid crystal display that employs the substrate once completed.

FIG. 3 is an enlarged view of an alternative form of appearance of the pixel the part shown corresponding to a plurality of pixels of a liquid crystal display that employs the substrate once completed.

FIG. 4 is a plan view of a mask layout according to the second embodiment of the present invention.

FIG. 5 is a plan view of a mask layout according to the third embodiment of the present invention.

FIG. 6 is a schematic plan view of a layout of a conventional mask.

FIG. 7 is a schematic, enlarged view of the stitching region 8, showing how it is finally formed over the course of two exposure steps in the above-described exposure procedure.

FIG. 8 is a schematic, enlarged view of portions of the regions 82, 83 where they adjoin each other, showing the stitching effect.

### DETAILED DESCRIPTION OF PREFERRED EMBODIMENTS

Referring to FIG. 1, this is a plan view of a mask 200 according to a first embodiment of the present invention, together with a substrate used with the mask in an exposing process according to a fourth embodiment of the present invention, the substrate having a stitching region formed thereon. The mask 200 includes three blocks including block I, block II, and block III. The boundary shape of each of the adjacent two blocks includes alternated linear shape portion and curve shape portion. The exposing steps include forming a thin film transistor (TFT) electrode pattern on the glass substrate 100 by projecting light beams to the substrate 100 through the mask 200 then exposing the substrate 100 from left side to right side so as to form an exposed area 11 through block I. Subsequently, three exposed areas 12, 13, 14 are formed by illuminate the block II of the mask 200 sequentially. Finally, an exposed area 15 is formed by exposing through block III of the mask 200.

It should be noted that the boundary structure of each two exposed areas is not shaped as linear and is shaped as nonlinear structure instead. The preferred embodiment of the nonlinear structure is an alternative linear portion, and curve portion. The preferred embodiment to form the nonlinear structure of the exposed area does not increase difficulty of design and process flow.

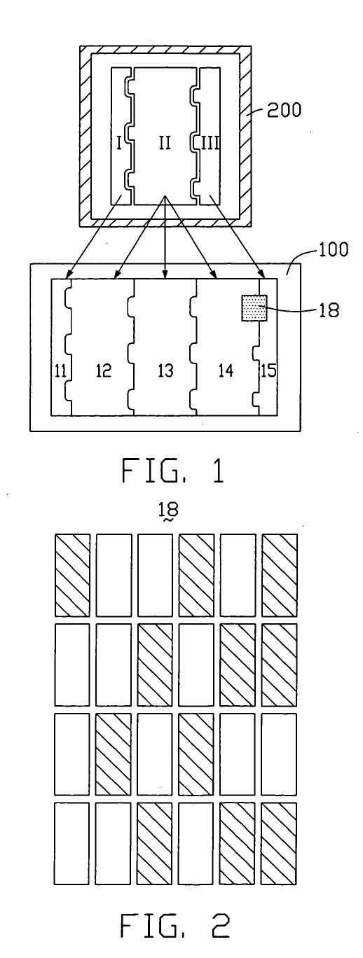

Referring to FIG. 2, this is an enlarged view of part of the stitching region shown in FIG. 1, the part shown corresponding to a plurality of pixels of a liquid crystal display that employs the substrate once completed. As shown in the drawing, the bright pixels and the dark pixels are arranged irregularly due to dispersion of dark areas so as to mitigate the so-called beeline effect. Therefore, viewers cannot easily see a bright line or dark line in the viewing zone of display.

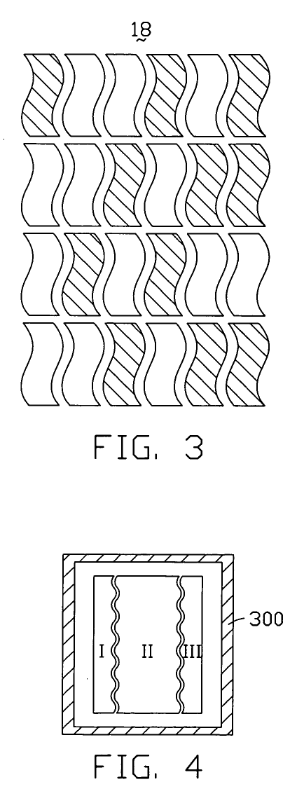

Referring to FIG. 3, this is an enlarged view of an alternative form of appearance of the pixel the part shown corresponding to a plurality of pixels of a liquid crystal display that employs the substrate once completed. The appearance of pixels may figure as S shape. This kind of structure can increase the difficulty for viewers to notice the beeline effect on the stitching area 18 exposed through the mask 200 so as to raise the viewing quality. Alternatively, the appearance of pixels can be a bending shape or another kind of shape such as crooked shape.

Referring to FIG. 4, this is a mask layout according to the second embodiment of the present invention. The mask 300 includes three blocks of block I, block II, and block III. The stitching areas between the aforesaid three blocks may figure as a curve shape.

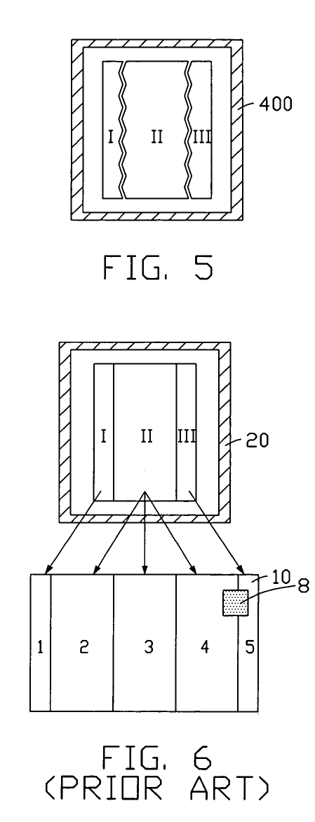

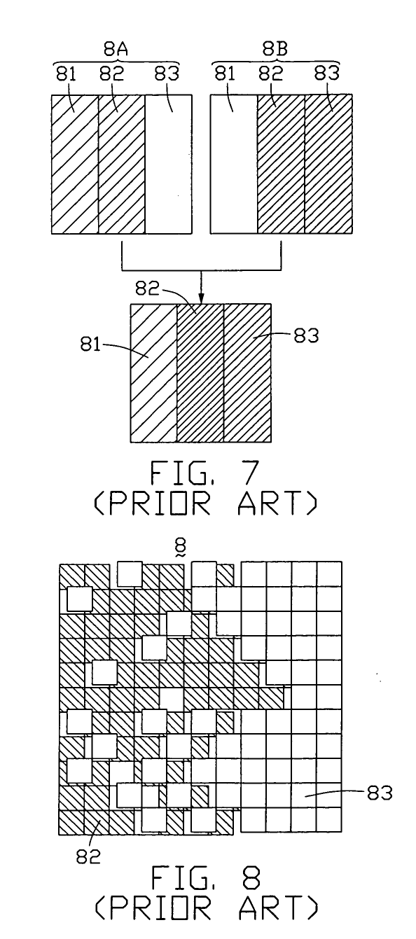

Referring to FIG. 5, this is a mask layout according to the third embodiment of the present invention. The mask 400 may include three blocks illustrating block I, block II, and block III. The stitching areas between the aforesaid three blocks may figure as a bending shape.

There may be other alternative embodiments, such as the stitching structure between each of two blocks can be an alternate combination of a curve segment and a bending segment or an alternate combination of a linear segment and a bending segment. It is noted that three blocks in the aforementioned mask 200, 300, and 400 are to be taken as examples only. The number of blocks and the corresponding dimensions can be adjustable according to the size of the glass substrate.

As would be understood by a person skilled in the art, the foregoing preferred and exemplary embodiments illustrate the present invention rather than limit the present invention. The embodiments are intended to cover various modifications and similar arrangements included within the spirit and scope of the appended claims, the scope of which should be accorded the broadest interpretation so as to encompass all such modifications and similar structures.

We claim:

1. A mask comprising a plurality of blocks, wherein the a stitching area between two adjacent blocks is nonlinear.

2. The mask as claimed in claim 1, wherein the nonlinear stitching area is curved.

3. The mask as claimed in claim 1, wherein the nonlinear stitching area is bent.

4. The mask as claimed in claim 1, wherein the nonlinear stitching area is a combination of alternating linear portions and curved portions.

5. The mask as claimed in claim 1, wherein the nonlinear stitching area is a combination of alternating linear portions and bent portions.

6. The mask as claimed in claim 1, wherein the nonlinear stitching area is a combination of curved portions and bent portions.

7. The mask as claimed in claim 1, wherein each of the blocks corresponds to a plurality of pixel units of a substrate corresponding to the mask, and the blocks are configured to produce the pixel units in crooked configurations.

8. The mask as claimed in claim 7, wherein the blocks are configured to produce the pixel units in S shapes.

9. The mask as claimed in claim 7, wherein the blocks are configured to produce the pixel units in bent shapes.

10. An exposing method for using a mask to mitigate a stitching effect, the mask comprising at least a first block and a second block adjoining the first block, the method comprising:
forming a first exposed area on a target substrate by exposing the substrate with light through the first block of the mask; and
forming a second exposed area on the substrate by exposing the substrate through the second block of the mask;
wherein a stitching area where the first block and the second block adjoin each other is nonlinear.

11. The exposing method as claimed in claim 10, wherein the nonlinear stitching area is curved.

12. The exposing method as claimed in claim 10, wherein the nonlinear stitching area is bent.

13. The exposing method as claimed in claim 10, wherein the nonlinear stitching area is a combination of alternating linear portions and curved portions.

14. The exposing method as claimed in claim 10, wherein the nonlinear stitching area is a combination of alternating linear portions and bent portions.

15. The exposing method as claimed in claim 10, wherein the nonlinear stitching area is a combination of curved portions and bent portions.

16. A mask comprising a plurality of blocks, wherein the a stitching area between two adjacent blocks is irregular.
